(19) United States
(12) Patent Application Publication
(10) Pub. No.: US 2010/0052055 A1
(43) Pub. Date: Mar. 4, 2010

(54) Semiconductor device having vertical field effect transistor and method of manufacturing the same

(75) Inventor: Kiyoshi Takeuchi, Kanagawa (JP)

Correspondence Address: MCGINN INTELLECTUAL PROPERTY LAW GROUP, PLLC, 8321 OLD COURTHOUSE ROAD, SUITE 200, VIENNA, VA, 22182-3817, US

(73) Assignee: NEC ELECTRONICS CORPORATION, Kawasaki (JP)

(21) Appl. No.: 12/461,433

(22) Filed: Aug. 11, 2009

(30) Foreign Application Priority Data
Aug. 27, 2008 (JP) 2008-218155

(51) Int. Cl. H01L 27/092

(52) U.S. Cl. 257/351; 257/E27.062

(57) ABSTRACT

A semiconductor device has: an insulating substrate; a first semiconductor layer of a first conductivity type formed on the insulating substrate; a first vertical field effect transistor of the first conductivity type, one of whose source and drain being formed on the first semiconductor layer; a second semiconductor layer of a second conductivity type formed on the insulating substrate; and a second vertical field effect transistor of the second conductivity type, one of whose source and drain being formed on the second semiconductor layer. The first semiconductor layer and the second semiconductor layer are directly in contact with each other.

### INCORPORATION BY REFERENCE

This application is based upon and claims the benefit of priority from Japanese patent application No. 2008-218155, filed on Aug. 27, 2008, the disclosure of which is incorporated herein in its entirety by reference.

### BACKGROUND OF THE INVENTION

1. Field of the Invention

The present invention relates to a semiconductor device. In particular, the present invention relates to a semiconductor device having a vertical field effect transistor and a method of manufacturing the same.

2. Description of Related Art

A MISFET (Metal Insulator Semiconductor Field Effect Transistor) has been miniaturized, which achieves improvement in integration and performance. In recent years, the MISFET reaches a level where a thickness of its gate insulating film is less than 2 nm and its gate length is less than 50 nm. However, further miniaturization of a typical MISFET is becoming more difficult, because it causes problems such as increase in leakage current and characteristics variability. That is, it is becoming more difficult to further improve the integration with using a typical MISFET.

In recent years, use of “vertical MISFET” has been proposed for the purpose of improving the integration. The vertical MISFET is described, for example, in Japanese Laid-Open Patent Application JP-H06-069441, Japanese Laid-Open Patent Application JP-H07-099311, Japanese Laid-Open Patent Application JP-H08-088328, Japanese Laid-Open Patent Application JP-H09-232447, Japanese Laid-Open Patent Application JP-2002-158350 and Japanese Laid-Open Patent Application JP-2003-163282. In a case of a typical planar MISFET, a channel current flows in a horizontal direction parallel to a substrate surface. In contrast, a vertical MISFET has a structure in which a channel current flows in a vertical direction perpendicular to a substrate surface. Using such a vertical MISFET enables reduction in an occupation area on a substrate, as compared with the case of the planar MISFET. That is to say, it is possible to improve the integration by utilizing the vertical MISFET.

FIG. 1 is a cross-sectional view showing an example of a semiconductor device using a vertical MISFET. As shown in FIG. 1, an N-channel vertical MISFET (hereinafter referred to as NFET) and a P-channel vertical MISFET (hereinafter referred to as PFET) are formed on a bulk semiconductor substrate SB.

The NFET has source/drain sections BNSD and TNSD which are N-type diffusion regions. One source/drain section BNSD among them is formed into and protruding from a surface of the bulk semiconductor substrate SB. A channel section CH, which reaches the surface of the bulk semiconductor substrate SB, is formed on the source/drain section BNSD, and further the other source/drain section TNSD is formed on the channel section CH. That is, the channel section CH is sandwiched in the vertical direction between the source/drain sections BNSD and TNSD. A gate electrode GT is formed on the channel section CH through a gate insulating film GD. The N-channel vertical MISFET is thus configured.

The PFET has source/drain sections BPSD and TPSD which are P-type diffusion regions. One source/drain section BPSD among them is formed into and protruding from the surface of the bulk semiconductor substrate SB. A channel section CH, which reaches the surface of the bulk semiconductor substrate SB, is formed on the source/drain section BPSD, and further the other source/drain section TPSD is formed on the channel section CH. That is, the channel section CH is sandwiched in the vertical direction between the source/drain sections BPSD and TPSD. A gate electrode GT is formed on the channel section CH through a gate insulating film GD. The P-channel vertical MISFET is thus configured.

A large number of NFETs and PFETs are formed on the bulk semiconductor substrate SB. In this case, in order to electrically separate the transistors from each other, a P well region PW and an N well region NW are formed in the bulk semiconductor substrate SB. The plurality of NFETs are formed on the P well region PW, while the plurality of PFETs are formed on the N well region NW. Moreover, a ground potential is applied to the P well region PW, and a power-supply potential is applied to the N well region NW. As a result, electrical isolation is achieved, due to reverse bias, between the source/drain section BNSD of the NFET and the P well region PW, between the source/drain section BPSD of the PFET and the N well region NW, and between the P well region PW and the N well region NW, respectively. Furthermore, a device isolation structure STI is formed between the source/drain section BNSD of the NFET and the source/drain section BPSD of the PFET. The device isolation structure STI prevents the source/drain section BNSD of the NFET from being in contact with the N well region NW and prevents the source/drain section BPSD of the PFET from being in contact with the P well region PW. The isolation between the NFET and the PFET is achieved by the above configuration.

Meanwhile, it is often required in a semiconductor integrated circuit to electrically connect source/drain sections of two or more transistors with each other. For example, in a case of a complementary-type inverter (CMIS inverter) using an N-channel MISFET and a P-channel MISFET, it is required to short-circuit drains of the N-channel MISFET and the P-channel MISFET to each other.

The above-mentioned Japanese Laid-Open Patent Application JP-2002-158350 and Japanese Laid-Open Patent Application JP-2003-163282 disclose a complementary-type inverter using such a vertical MISFET as shown in FIG. 1. In this case, it is required to short-circuit drains of necessary NFET and PFET on the bulk semiconductor substrate SB to each other. More specifically, as shown in FIG. 1, the source/drain section BNSD of the NFET and the source/drain section BPSD of the PFET are electrically connected with each other through a local metal wiring LI. It should be noted here that the local metal wiring LI is so formed as to stride over the device isolation structure STI located between the source/drain sections BNSD and BPSD and is in contact with both of the source/drain sections BNSD and BPSD.

Moreover, as shown in FIG. 1, the other source/drain section TNSD of the NFET is connected to a ground line Gnd, and the other source/drain section TPSD of the PFET is connected to a power-supply line Vdd. Furthermore, the gate electrodes GT of the NFET and the PFET are connected to a common input line In, and the source/drain section BNSD of the NFET is connected to an output line Out. Consequently, the complementary-type inverter that outputs an inversion data of a data input to the input line In to the output line Out is configured.

Note that the complementary-type inverter is constituted only by the necessary NFET and PFET on the bulk semiconductor substrate SB. That is, the local metal wiring LI is selectively formed such that only the source/drain sections BNSD and BPSD of the necessary NFET and PFET are short-circuited to each other. The other NFETs and PFETs are electrically isolated from each other as described above, such that the semiconductor integrated circuit operates normally.

The inventor of the present application has recognized the following points. In the case of the structure shown in FIG. 1, the integration cannot be improved further. The reason is as follows.

First, it is required to form the device isolation structure STI between the source/drain sections BNSD and BPSD in order to prevent the source/drain section BNSD of the NFET from being in contact with the N well region NW and to prevent the source/drain section BPSD of the PFET from being in contact with the P well region PW. That is to say, the NFET and the PFET need to be separated by the device isolation structure STI, and thus it is not possible to make the NFET and the PFET closer to each other. This interferes improvement in the integration.

Moreover, in the case where the complementary-type inverter is formed for example, it is required to short-circuit the source/drain section BNSD of the NFET and the source/drain section BPSD of the PFET to each other. For that purpose, the local metal wiring LI striding over the device isolation structure STI to be in contact with both of the source/drain sections BNSD and BPSD is formed as shown in FIG. 1. Here, a contact resistance is caused between semiconductor of the source/drain sections BNSD and BPSD and metal of the local metal wiring LI. In order to reduce the contact resistance, it is necessary to secure a sufficient contact area. However, to secure a sufficient contact area between the source/drain sections (BNSD, BPSD) and the local metal wiring LI causes increase in a circuit area and hence deterioration in the integration.

### SUMMARY

In a first aspect of the present invention, a semiconductor device is provided. The semiconductor device has: an insulating substrate; a first semiconductor layer of a first conductivity type formed on the insulating substrate; a first vertical field effect transistor of the first conductivity type, one of whose source and drain being formed on the first semiconductor layer; a second semiconductor layer of a second conductivity type formed on the insulating substrate; and a second vertical field effect transistor of the second conductivity type, one of whose source and drain being formed on the second semiconductor layer. The first semiconductor layer and the second semiconductor layer are directly in contact with each other.

In a second aspect of the present invention, a semiconductor device is provided. The semiconductor device has: an insulating substrate; a first semiconductor layer of a first conductivity type formed on the insulating substrate; a first vertical field effect transistor of the first conductivity type, one of whose source and drain being formed on the first semiconductor layer; a second semiconductor layer of a second conductivity type formed on the insulating substrate; a second vertical field effect transistor of the second conductivity type, one of whose source and drain being formed on the second semiconductor layer; and a metal layer formed to be in contact with both of the first semiconductor layer and the second semiconductor layer. At least a part of the metal layer is formed below an upper surface of the first semiconductor layer and the second semiconductor layer.

In a third aspect of the present invention, a method of manufacturing a semiconductor device is provided. The method includes: (A) forming a first semiconductor layer of a first conductivity type and a second semiconductor layer of a second conductivity type on an insulating substrate, wherein the first semiconductor layer and the second semiconductor layer are directly in contact with each other; and (B) forming a first vertical field effect transistor of the first conductivity type and a second vertical field effect transistor of the second conductivity type, wherein one of source and drain of the first vertical field effect transistor is connected to the first semiconductor layer, and one of source and drain of the second vertical field effect transistor is connected to the second semiconductor layer.

According to the present invention, it is possible to further improve the integration in the semiconductor device using the vertical field effect transistor.

### BRIEF DESCRIPTION OF THE DRAWINGS

The above and other objects, advantages and features of the present invention will be more apparent from the following description of certain preferred embodiments taken in conjunction with the accompanying drawings, in which:

FIG. 1 is a cross-sectional view showing a structure of a complementary-type inverter using a vertical MISFET described in a related technique;

FIG. 2 is a cross-sectional view showing a structural example of a semiconductor device according to an embodiment of the present invention;

FIG. 3A is a top view of the structure seen from A-A′ in FIG. 2;

FIG. 3B is a top view of the structure seen from B-B′ in FIG. 2;

FIG. 3C is a top view of the structure shown in FIG. 2;

FIG. 4 is a circuit diagram of the semiconductor device shown in FIG. 2;

FIGS. 5A to 5J are cross-sectional views showing a manufacturing process of the semiconductor device according to the present embodiment;

FIG. 6 is a top view showing a manufacturing process of the semiconductor process according to the present embodiment;

FIG. 7 is a top view showing a first modification example;

FIG. 8 is a cross-sectional view showing the first modification example;

FIG. 9 is a cross-sectional view showing a second modification example; and

FIG. 10 is a cross-sectional view showing a third modification example.

### DESCRIPTION OF PREFERRED EMBODIMENTS

The invention will be now described herein with reference to illustrative embodiments. Those skilled in the art will recognize that many alternative embodiments can be accomplished using the teachings of the present invention and that the invention is not limited to the embodiments illustrated for explanatory purposed.

A semiconductor device according to an embodiment of the present invention is provided with two different types of vertical MISFETs of different conductivity types. The first vertical MISFET is “N-channel vertical MISFET (hereinafter referred to as NFET)” whose conductivity type is the N-type. On the other hand, the second vertical MISFET is “P-channel vertical MISFET (hereinafter referred to as PFET)” whose conductivity type is the P-type. It is possible by using these NFET and PFET of vertical-type to develop various devices with improving the integration. As an example, a complementary-type inverter (CMIS inverter) using the NFET and PFET will be described below. In this case, it is necessary to short-circuit source/drain sections of the NFET and PFET to each other.

### 1. STRUCTURE

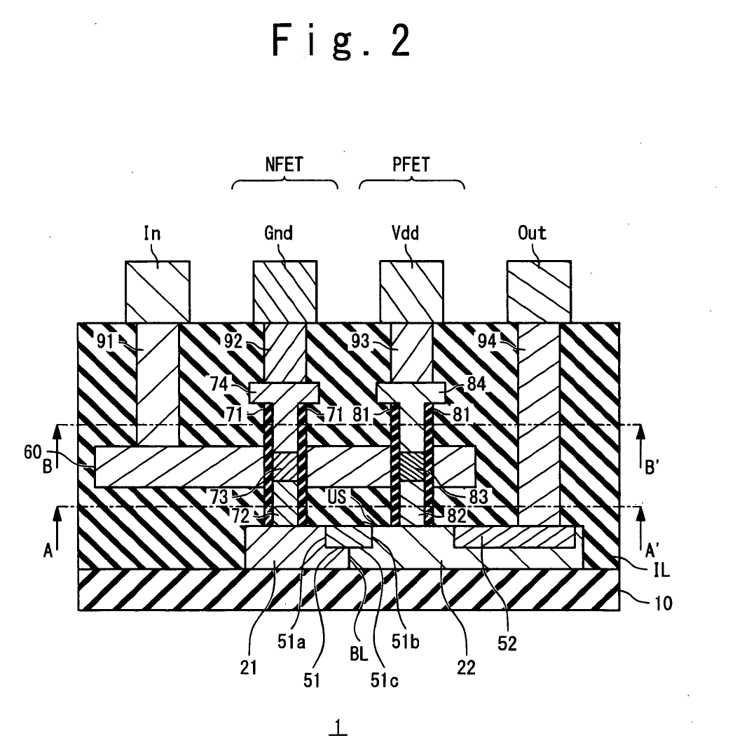

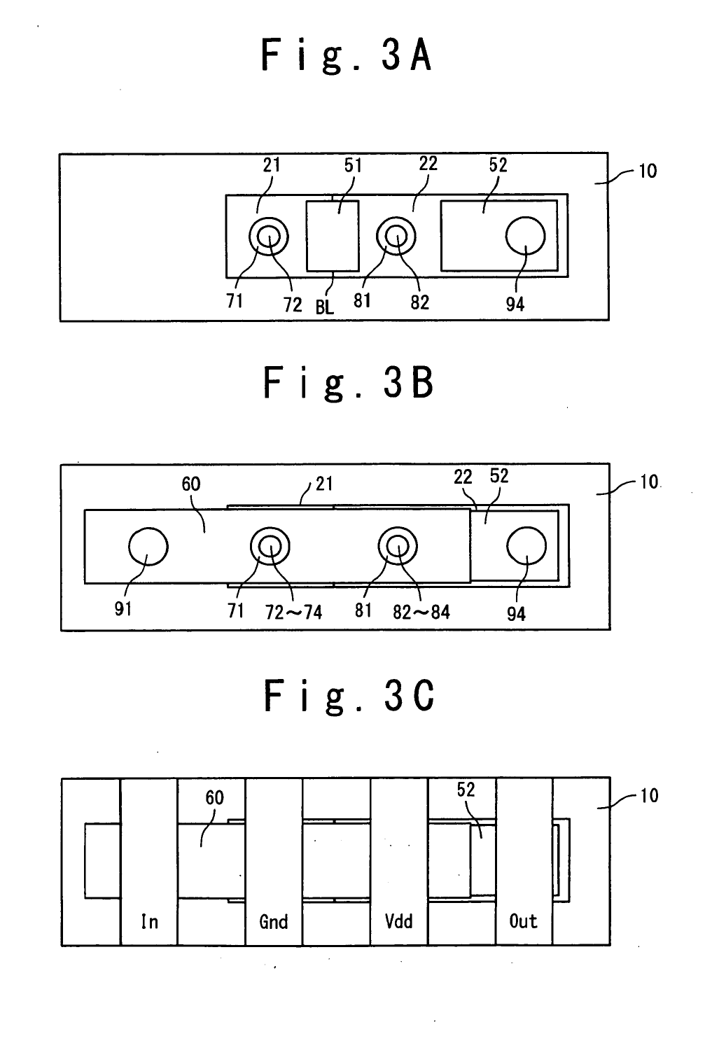

FIG. 2 is a cross-sectional view showing a structural example of a semiconductor device 1 as a complementary-type inverter according to the present embodiment. FIG. 3A is a top view of the structure seen from A-A′ in FIG. 2. FIG. 3B is a top view of the structure seen from B-B′ in FIG. 2. FIG. 3C is a top view of the structure shown in FIG. 2. Note that an interlayer insulating film IL is not illustrated in FIGS. 3A to 3C.

In the present embodiment, an insulating substrate 10 is used as a substrate. For example, a silicon oxide film is formed on a silicon substrate, and then it is used as the insulating substrate 10. A single-crystal semiconductor layer is formed on the insulating substrate 10. If the semiconductor layer is formed of silicon, the so-called SOI (Silicon On Insulator) structure is obtained. The GOI (Germanium On Insulator) structure using germanium or the SGOI (Silicon-Germanium On Insulator) structure using silicon-germanium is also possible.

The semiconductor layer formed on the insulating substrate 10 is used as a base for forming the NFET and PFET. More specifically, as shown in FIG. 2, an N-type semiconductor layer 21 and a P-type semiconductor layer 22 are formed on the insulating substrate 10. The NFET is formed on the N-type semiconductor layer 21 of the same conductivity type, and the PFET is formed on the P-type semiconductor layer 22 of the same conductivity type.

The NFET has a columnar structure formed on the N-type semiconductor layer 21. The columnar structure includes source/drain sections 72 and 74 which are N-type diffusion regions and a channel section 73. The lower source/drain section 72 among the source/drain sections 72 and 74 is formed on the N-type semiconductor layer 21 and is connected to the N-type semiconductor layer 21. The channel section 73 is formed on the lower source/drain section 72, and the upper source/drain section 74 is formed on the channel section 73. That is, the channel section 73 is sandwiched in the vertical direction between the source/drain sections 72 and 74. Moreover, a first gate insulating film 71 is so formed as to cover around a side surface of the columnar structure. Furthermore, a gate electrode 60 is formed on a side surface of the channel section 73 through the first gate insulating film 71. That is, the gate electrode 60 is so formed as to cover around the channel section 73 through the first gate insulating film 71 (see FIG. 3B). The NFET is thus configured such that a channel current flows in the vertical direction perpendicular to the substrate surface.

The PFET has a columnar structure formed on the P-type semiconductor layer 22. The columnar structure includes source/drain sections 82 and 84 which are P-type diffusion regions and a channel section 83. The lower source/drain section 82 among the source/drain sections 82 and 84 is formed on the P-type semiconductor layer 22 and is connected to the P-type semiconductor layer 22. The channel section 83 is formed on the lower source/drain section 82, and the upper source/drain section 84 is formed on the channel section 83. That is, the channel section 83 is sandwiched in the vertical direction between the source/drain sections 82 and 84. Moreover, a second gate insulating film 81 is so formed as to cover around a side surface of the columnar structure. Furthermore, a gate electrode 60 is formed on a side surface of the channel section 83 through the second gate insulating film 81. That is, the gate electrode 60 is so formed as to cover around the channel section 83 through the second gate insulating film 81 (see FIG. 3B). The PFET is thus configured such that a channel current flows in the vertical direction perpendicular to the substrate surface.

The conductivity type of the channel sections 73 and 83 can be any of the N-type, the P-type and the I-type where no impurity is doped, and is selected appropriately such that a desired threshold voltage is achieved. As the gate insulating films 71 and 81, a silicon oxide film, a silicon nitride film, a hafnium oxide film, a hafnium oxynitride film or a laminated film thereof can be used for example. As material of the gate electrode 60, semiconductor such as doped silicon or metal with high stability such as titanium nitride and aluminum can be used for example.

A cross-sectional shape of the channel sections 73 and 83 (columnar structure) is not limited to circle shown in FIG. 3B and can be ellipse, square or rectangle. Note that it is preferable that a size of the cross-sectional shape (a diameter in the case of circle, a length of the minor axis in the case of ellipse, a length of the short side in the case of rectangle) is designed to be half the channel length or less in order to prevent the short channel effect.

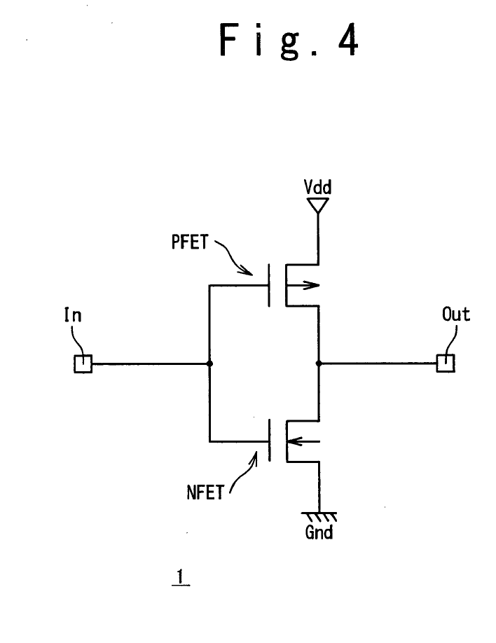

According to the present embodiment, a complementary-type inverter as shown in FIG. 4 is configured by the use of the above-described NFET and PFET. For that purpose, contact plugs 91 to 94 are so formed as to penetrate the interlayer insulating film IL to reach the NFET or the PFET, as shown in FIG. 2. An input line In to which an input data is input, a ground line Gnd to which the ground potential is supplied, a power-supply line Vdd to which the power-supply potential is supplied, and an output line Out from which an output data is output are formed on the interlayer insulating film IL. The input line In, the ground line Gnd, the power-supply line Vdd and the output line Out are connected to the contact plugs 91 to 94, respectively.

The input line In is connected to the gate electrodes 60 of the NFET and PFET through the contact plug 91. In the present embodiment, the gate electrode 60 of the NFET and the gate electrode 60 of the PFET are common and formed integrally. As shown in FIG. 3B, the gate electrode 60 is so formed as to cover around the columnar structures of the NFET and the PFET. In other words, the columnar structures of the NFET and the PFET are so formed as to penetrate through the gate electrode 60. However, the structure related to the gate electrode 60 is not limited to the above-described one. Any structure is possible as long as the channel current flows through the channel sections 73 and 83. For example, the gate electrode 60 does not need to entirely surround the channel sections 73 and 83. The gate electrode 60 of the NFET and the gate electrode 60 of the PFET may be formed separately from each other.

The ground line Gnd is connected to the upper source/drain section 74 of the NFET through the contact plug 92. Therefore, the ground potential is supplied to the source/drain section 74 of the NFET. The power-supply line Vdd is connected to the upper source/drain section 84 of the PFET through the contact plug 93. Therefore, the power-supply potential is supplied to the source/drain section 84 of the PFET.

Moreover, the lower source/drain section 72 of the NFET and the lower source/drain section 82 of the PFET are electrically connected with each other. That is to say, the N-type semiconductor layer 21 connected to the source/drain section 72 of the NFET and the P-type semiconductor layer 22 connected to the source/drain section 82 of the PFET are short-circuited to each other. In the example shown in FIG. 2, the N-type semiconductor layer 21 and the P-type semiconductor layer 22 are formed to be directly in contact with each other. A contact boundary between the N-type semiconductor layer 21 and the P-type semiconductor layer 22 is represented by a reference numeral “BL”.

Furthermore, a first metal layer 51 is so formed as to be in contact with both of the N-type semiconductor layer 21 and the P-type semiconductor layer 22 in order to more completely short-circuit the N-type semiconductor layer 21 and the P-type semiconductor layer 22 to each other. More specifically, the first metal layer 51 is formed over the contact boundary BL between the N-type semiconductor layer 21 and the P-type semiconductor layer 22. The first metal layer 51 more completely short-circuits the N-type semiconductor layer 21 and the P-type semiconductor layer 22 to each other. Note that it is preferable that the first metal layer 51 is formed of high heat resistance metal silicide such as tungsten silicide, titanium silicide and cobalt silicide.

When sufficiently high concentration of impurities are introduced into the N-type semiconductor layer 21 and the P-type semiconductor layer 22, the semiconductor layers 21, 22 and the first metal layer 51 exhibit resistive contact characteristics. It should be noted that a contact resistance is caused at a contact section between the semiconductor layers 21, 22 and the first metal layer 51. In order to reduce the contact resistance, it is preferable to secure as large contact area as possible. In order to enlarge the contact area, the first metal layer 51 is preferably formed to be embedded in the N-type semiconductor layer 21 and the P-type semiconductor layer 22, as shown in FIG. 2. In other words, at least a part of the first metal layer 51 is preferably formed below an upper surface US of the N-type semiconductor layer 21 and the P-type semiconductor layer 22. In this case, the first metal layer 51 has a first side surface 51a being in contact with the N-type semiconductor layer 21, a second side surface 51b being in contact with the P-type semiconductor layer 22, and a bottom surface 51c being in contact with both of the N-type semiconductor layer 21 and the P-type semiconductor layer 22. That is to say, the first metal layer 51 can be in contact with the semiconductor layers 21 and 22 at its side surfaces and bottom surface. As a result, the contact area is enlarged and parasitic resistance is reduced, which is preferable.

As described above, the N-type semiconductor layer 21 and the P-type semiconductor layer 22 are short-circuited to each other and thereby the source/drain section 72 of the NFET and the source/drain section 82 of the PFET are short-circuited to each other. Moreover, they are electrically connected to the output line Out. To that end, either one of the N-type semiconductor layer 21 and the P-type semiconductor layer 22 is extended to be connected to the contact plug 94. In the example shown in FIG. 2, the P-type semiconductor layer 22 is so extended as to be electrically connected to the output line Out through the contact plug 94.

Here, as shown in FIG. 2, a second metal layer 52 may be formed to be in contact with the P-type semiconductor layer 22 such that the second metal layer 52 is connected to the output line Out through the contact plug 94. In this case, a resistance of a signal path to the output line Out is reduced, which is preferable. As in the case of the first metal layer 51, the second metal layer 52 is preferably formed of high heat resistance metal silicide such as tungsten silicide, titanium silicide and cobalt silicide. Moreover, it is preferable that the second metal layer 52 is formed to be embedded in the P-type semiconductor layer 22, as in the case of the first metal layer 51. In other words, at least a part of the second metal layer 52 is formed below the upper surface US of the P-type semiconductor layer 22 such that the second metal layer 52 is in contact with the P-type semiconductor layer 22 at its side surface and bottom surface. As a result, a contact area between the second metal layer 52 and the P-type semiconductor layer 22 is enlarged and parasitic resistance is reduced.

It should be noted that the second metal layer 52 can be formed by the same manufacturing process as for the first metal layer 51. In this case, the first metal layer 51 and the second metal layer 52 are formed in the same layer as shown in FIG. 2. There is no need to add a specific process for providing the second metal layer 52 and thus no additional cost arises.

As described above, the complementary-type inverter as shown in FIG. 4, namely, the complementary-type inverter that outputs an inversion data of a data input to the input line In to the output line Out is configured.

### 2. EFFECTS

According to the present embodiment, the N-type semiconductor layer 21 connected to the source/drain section 72 of the NFET and the P-type semiconductor layer 22 connected to the source/drain section 82 of the PFET are short-circuited to each other. In the example shown in FIG. 2, the N-type semiconductor layer 21 and the P-type semiconductor layer 22 are so formed as to be directly contact with each other. It should be noted here that no device isolation structure is formed between the N-type semiconductor layer 21 and the P-type semiconductor layer 22. The N-type semiconductor layer 21 and the P-type semiconductor layer 22 are directly connected to each other without through a device isolation structure. Thus, there is no need to secure an area for providing a device isolation structure, which improves the integration.

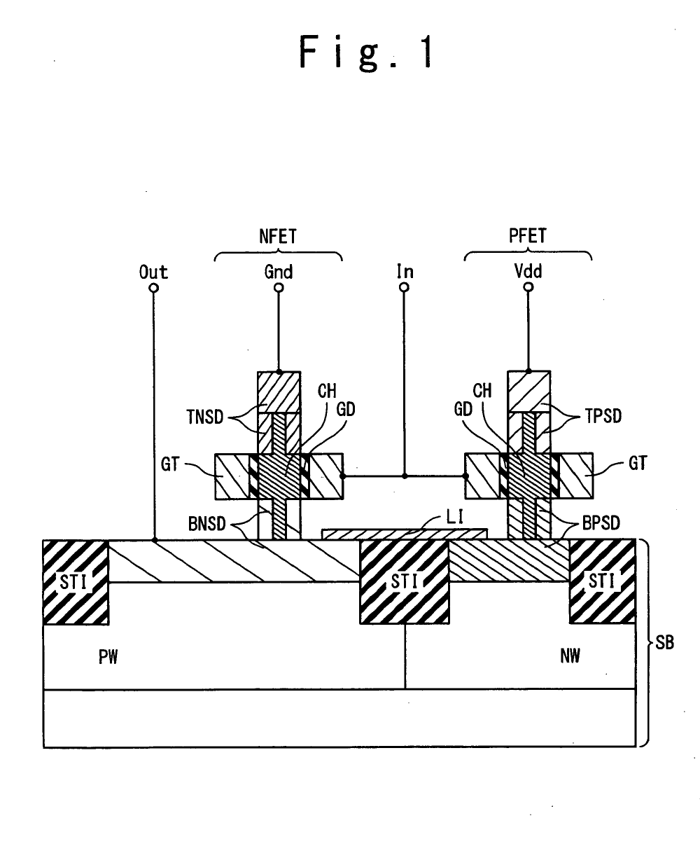

As a comparative example, let us consider the case shown in FIG. 1 mentioned above. In the case of FIG. 1, it is required to form the P well region PW and the N well region NW in order to electrically isolate the source/drain sections of the NFET and PFET from the bulk semiconductor substrate SB. Moreover, it is required to form the device isolation structure STI between the source/drain section BNSD of the NFET and the source/drain section BPSD of the PFET. If the device isolation structure STI is not formed, displacement during the manufacturing process causes either short-circuit between the source/drain section BNSD of the NFET and the N well region NW or short-circuit between the source/drain section BPSD of the PFET and the P well region PW. In that case, a large leakage current flows between the source/drain section BNSD of the NFET and the N well region NW to which the power-supply potential is applied or between the source/drain section BPSD of the PFET and the P well region PW to which the ground potential is applied, which makes a normal circuit operation impossible. Therefore, the device isolation structure STI cannot be excluded. Consequently, it is not possible to make the NFET and PFET closer to each other, which interferes improvement in the integration.

On the other hand, according to the present embodiment, the insulating substrate 10 is used instead of the bulk semiconductor substrate. In this case, there is no need to form the P well region and N well region for isolating the source/drain sections of the NFET and PFET from the substrate. Therefore, the device isolation structure STI as shown in FIG. 1 is not necessary, and it is thus possible to directly contact the N-type semiconductor layer 21 and the P-type semiconductor layer 22 to each other. Since there is no need to secure an area for providing a device isolation structure, the integration is improved.

It is preferable to provide the above-mentioned first metal layer 51 in order to more completely short-circuit the N-type semiconductor layer 21 and the P-type semiconductor layer 22. The first metal layer 51 can be formed to be embedded in the N-type semiconductor layer 21 and the P-type semiconductor layer 22. That is, the side surfaces (51a, 51b) and the bottom surface (51c) of the first metal layer 51 can be in contact with the semiconductor layers 21 and 22. As a result, the contact area between the first metal layer 51 and the semiconductor layers (21, 22) is increased and the parasitic resistance is reduced.

As a comparative example, let us consider the case shown in FIG. 1 mentioned above. In the case of FIG. 1, the local metal wiring LI is formed to be in contact with both of the source/drain section BNSD of the NFET and the source/drain section BPSD of the PFET in order to short-circuit them to each other. Here, the device isolation structure STI is provided between the source/drain sections BNSD and BPSD, and the local metal wiring LI is so formed as to stride over the device isolation structure STI. That is to say, the local metal wiring LI needs to be formed longer by the device isolation structure STI. Moreover, the local metal wiring LI is not embedded in the substrate. Therefore, in order to secure a sufficient contact area between the local metal wiring LI and the source/drain sections (BNSD, BPSD), it is necessary to make the local metal wiring LI further longer on the source/drain sections BNSD and BPSD. To form such the long local metal wiring LI causes increase in area and deterioration in the integration.

On the other hand, according to the present embodiment, no device isolation structure is formed between the N-type semiconductor layer 21 and the P-type semiconductor layer 22. Therefore, the first metal layer 51 need not be formed to stride over the device isolation structure, and thus the first metal layer 51 can be made small in length. Furthermore, the first metal layer 51 can be formed to be embedded in the N-type semiconductor layer 21 and the P-type semiconductor layer 22. In this case, the contact area between the first metal layer 51 and the semiconductor layers (21, 22) is increased even with a small plane area. The first metal layer 51 need not be made unnecessarily long, which also contributes to increase in the integration.

It should be noted that wirings (interconnections) are formed above transistors in a case of a typical semiconductor integrated circuit. The reason is that aluminum and copper, which are preferable for the wiring material for which low resistance is required, have low heat resistance and thus cannot resist high-temperature processes required for forming the transistors. Therefore, low-resistance aluminum wirings or copper wirings are typically formed above transistors after the formation of the transistors. However, in the case of the vertical MISFET, wirings may need to be formed below transistors because the lower source/drain sections exist.

In the case of FIG. 1, for example, the local metal wiring LI connecting between the source/drain section BNSD of the NFET and the source/drain section BPSD of the PFET needs to be formed before the NFET and PFET are completed. In this case, the local metal wiring LI should be formed of high heat resistance wiring material in order to resist the high-temperature processes. However, such high heat resistance wiring material generally has high resistance. Moreover, as mentioned above, the local metal wiring LI needs to be formed long due to the existence of the device isolation structure STI. In the case of the structure shown in FIG. 1, the long local metal wiring LI needs to be formed by the use of high resistance wiring material, and thus a resistance value of the local metal wiring LI is forced to be extremely high. This is not desirable from a view point of circuit characteristics.

On the other hand, according to the present embodiment, the first metal layer 51 can be made small in length, since the device isolation structure is eliminated from between the N-type semiconductor layer 21 and the P-type semiconductor layer 22. Therefore, slightly high resistance material is allowed for forming the first metal layer 51. For example, high heat resistance metal silicide such as tungsten silicide, titanium silicide and cobalt silicide can be used.

According to the present embodiment, as described above, it is possible to improve the integration in the semiconductor device using the vertical MISFET. In particular, the source/drain sections of the NFET and PFET can be electrically connected to each other with achieving small area and low resistance. Consequently, it is possible to provide a high-integration complementary-type semiconductor device by using the vertical MISFET.

### 3. MANUFACTURING METHOD

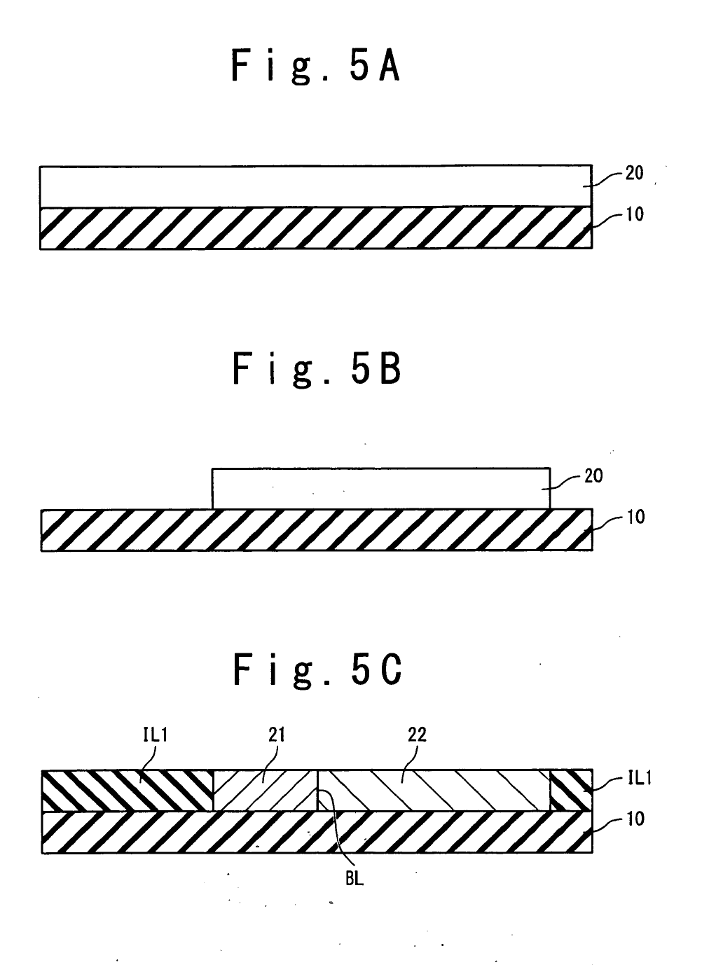

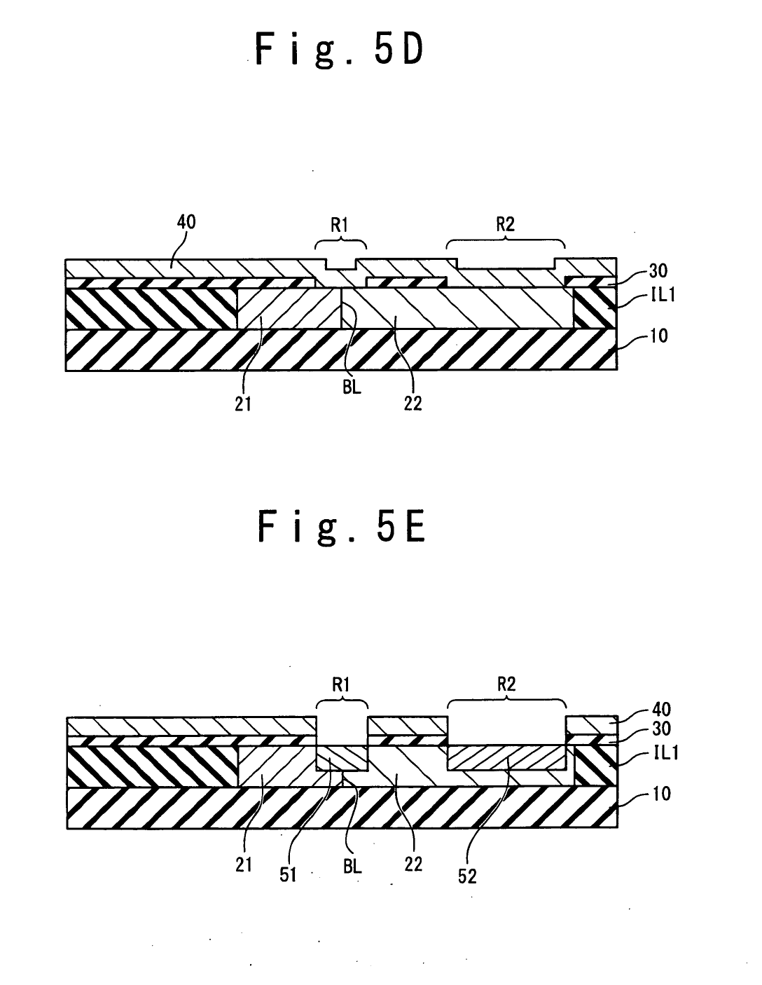

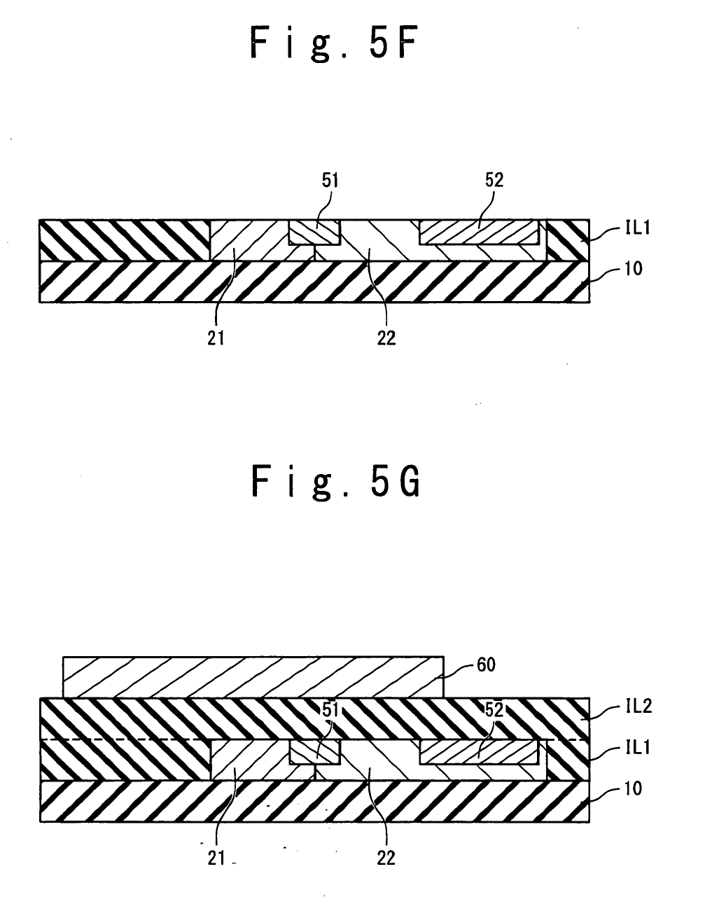

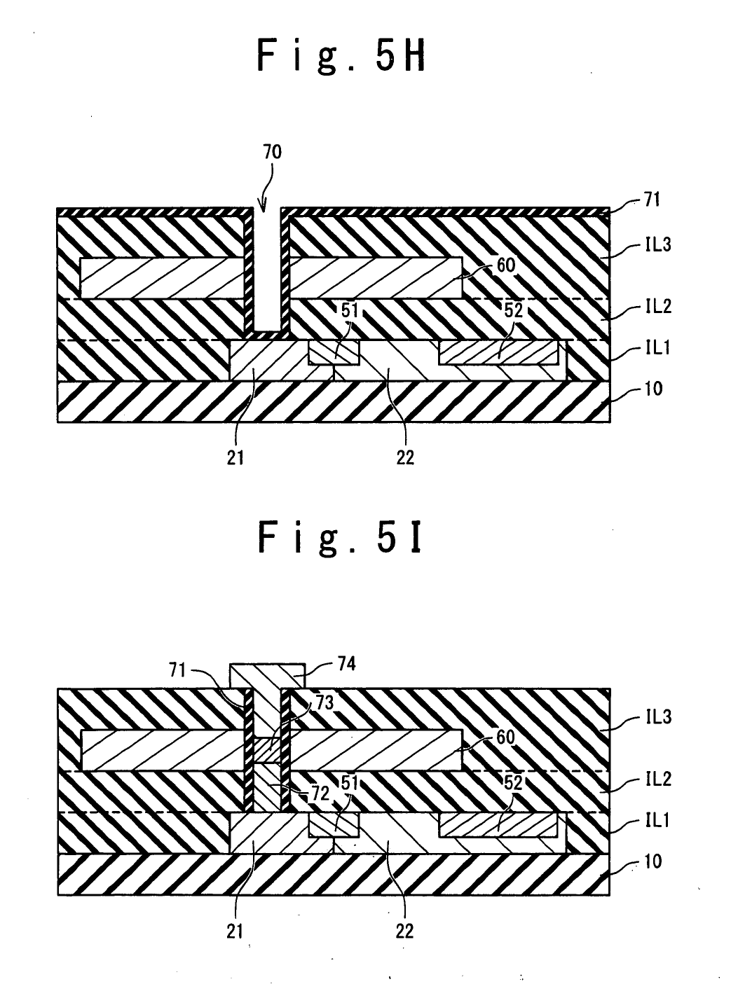

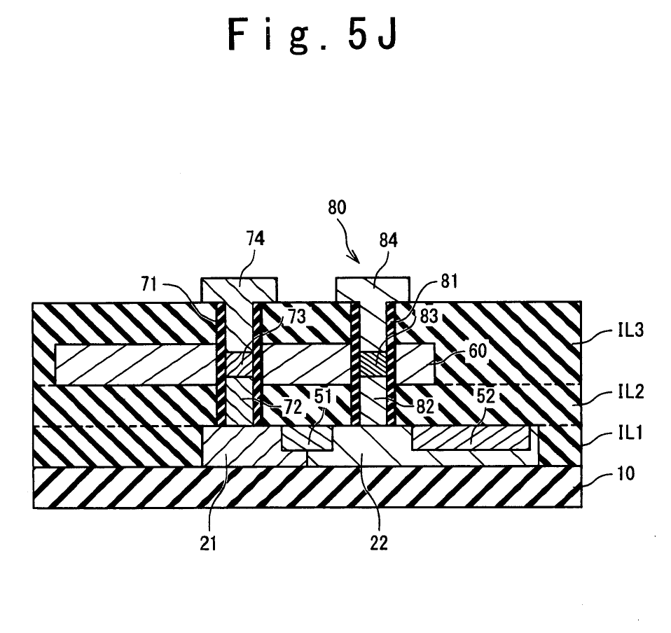

Next, a method of manufacturing the semiconductor device 1 according to the present embodiment will be described below with reference to FIGS. 5A to 5J. FIGS. 5A to 5J are cross-sectional views illustrating an example of a manufacturing process of the semiconductor device 1 according to the present embodiment.

First, as shown in FIG. 5A, a single-crystal semiconductor layer 20 is formed on an insulating substrate 10. The insulating substrate 10 is obtained, for example, by forming a silicon oxide film on a silicon substrate. In a case where the semiconductor layer 20 is formed of silicon, the so-called SOI structure is obtained. The GOI structure using germanium or the SGOI structure using silicon-germanium is also possible.

Next, as shown in FIG. 5B, the semiconductor layer 20 is processed to be a desired shape by the use of the well-known lithography technique and etching technique. The semiconductor layer 20 is used as a base for forming the NFET and PFET.

Next, an interlayer insulating film IL1 is blanket deposited by the CVD (Chemical Vapor Deposition) method or the like, and thereafter a surface of the interlayer insulating film IL1 is planarized by the CMP (Chemical Mechanical Polishing). Further, the interlayer insulating film IL1 is etched by the CMP or the well-known etching method until an upper surface of the semiconductor layer 20 is exposed. As a result, as shown in FIG. 5C, the semiconductor layer 20 is surrounded by the interlayer insulating film IL1, and a structure where the upper surface of the semiconductor layer 20 is exposed is obtained. Due to the planarization mentioned above, a fine pattern of the first metal layer 51 can be made easily in the later process. Note that this planarization process may be omitted.

Moreover, ion injection is performed such that N-type impurities are selectively introduced into the NFET base of the semiconductor layer 20 and P-type impurities are selectively introduced into the PFET base of the semiconductor layer 20. Consequently, as shown in FIG. 5C, an N-type semiconductor layer 21 and a P-type semiconductor layer 22 are formed on the insulating substrate 10. It should be noted here that the N-type semiconductor layer 21 and the P-type semiconductor layer 22 are directly in contact with each other. A contact boundary between the N-type semiconductor layer 21 and the P-type semiconductor layer 22 is represented by a reference numeral “BL”. Note that it makes no difference whether the N-type impurity injection or the P-type impurity injection is performed earlier.

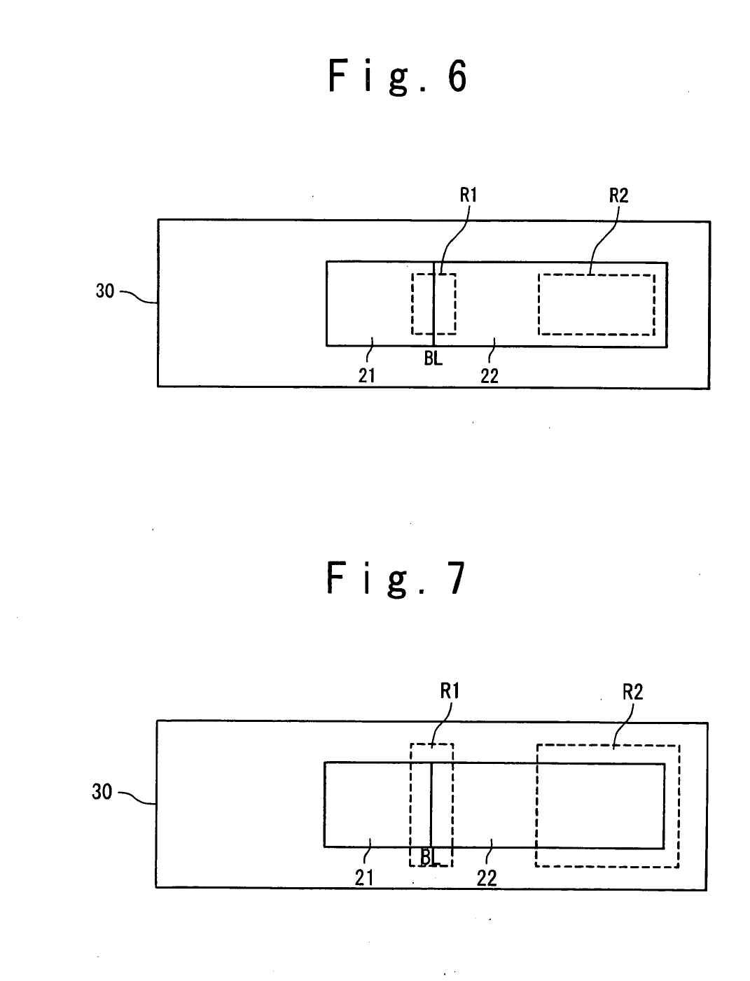

Next, an alloying inhibition film (cover film) 30 such as a silicon oxide film and a silicon nitride film is blanket formed. Subsequently, the well-known lithography technique and etching technique are used to form an opening at a region where a metal layer is formed later. More specifically, as shown in FIG. 5D and FIG. 6, a first opening R1 is formed at a region where the first metal layer 51 is formed and a second opening R2 is formed at a region where the second metal layer 52 is formed. In particular, the first opening R1 is formed over the contact boundary BL between the N-type semiconductor layer 21 and the P-type semiconductor layer 22. In this manner, the alloying inhibition film (cover film) 30 having the first opening R1 and the second opening R2 is formed. After that, as shown in FIG. 5D, a metal material film 40 used for alloying is blanket formed by the sputtering method or the like.

Next, a heat treatment is performed to alloy (silicide or germanide) the metal material film 40 and the semiconductor layers 21 and 22. More specifically, as shown in FIG. 5E, the first metal layer 51 is formed at the first opening R1 due to the alloying reaction between the metal material layer 40 and the semiconductor layers 21 and 22. At the same time, the second metal layer 52 is formed at the second opening R2 due to the alloying reaction between the metal material layer 40 and the P-type semiconductor layer 22. In this manner, the first metal layer 51 and the second metal layer 52 are formed in the same layer by the same manufacturing process.

The formed metal layers 51 and 52 depend on a combination of the metal material layer 40 and the semiconductor layer 20 (21, 22). If silicon is used as the semiconductor layer 20, metal silicide is obtained as the metal layers 51 and 52. If germanium is used as the semiconductor layer 20, metal germanide is obtained as the metal layers 51 and 52. For example, silicon is used as the semiconductor layer 20 and tungsten is used as the metal material layer 40, which is one preferable combination. In this case, tungsten silicide having high thermal stability is formed as the metal layers 51 and 52. Tungsten, titanium, cobalt, nickel, platinum or alloy thereof can also be used as the metal material layer 40. In either case, the high heat resistance metal layers 51 and 52 can be obtained.

As described above, the first opening R1 is formed over the contact boundary BL between the N-type semiconductor layer 21 and the P-type semiconductor layer 22. Therefore, the first metal layer 51 formed in the first opening R1 are so formed as to be in contact with both of the N-type semiconductor layer 21 and the P-type semiconductor layer 22. Moreover, as shown in FIG. 5E, the first metal layer 51 is formed to be embedded in the N-type semiconductor layer 21 and the P-type semiconductor layer 22 as a result of the alloying (silicidation or germanidation). In other words, at least a part of the first metal layer 51 is formed below the upper surface of the semiconductor layers 21 and 22 and hence the side surfaces and the bottom surface thereof are in contact with the semiconductor layers 21 and 22. As a result, the contact area between the first metal layer 51 and the semiconductor layers 21 and 22 is increased and the parasitic resistance is reduced. It should be noted that the semiconductor layers 21 and 22 are directly in contact with each other as shown in FIG. 5E and FIG. 6.

The same applies to the second metal layer 52 formed in the second opening R2. As shown in FIG. 5E, the second metal layer 52 is formed to be embedded in the P-type semiconductor layer 22. In other words, at least a part of the second metal layer 52 is formed below the upper surface of the P-type semiconductor layer 22 and hence the side surfaces and the bottom surface thereof are in contact with the P-type semiconductor layer 22. Consequently, the contact area between the second metal layer 52 and the P-type semiconductor layer 22 is increased and the parasitic resistance is reduced.

Next, the remaining metal material film 40, which did not react with the semiconductor, is removed by wet etching or the like. Furthermore, the alloying inhibition film 30 also is removed by wet etching or the like. As a result, a structure shown in FIG. 5F is obtained. It should be noted that the alloying inhibition film 30 may not be removed if the alloying inhibition film 30 is an insulating film.

Next, as shown in FIG. 5G, an interlayer insulating film IL2 is blanket deposited by the CVD method or the like. A surface of the interlayer insulating film IL2 may be planarized by the CMP, if necessary. Subsequently, a gate material layer which is material of a gate electrode 60 is blanket deposited. The gate material layer is processed to be a desired shape by the use of the well-known lithography technique and etching technique, and thereby the gate electrode 60 as shown in FIG. 5G is formed. As the material of the gate electrode 60, semiconductor such as doped silicon or metal with high stability such as titanium nitride and aluminum can be used for example.

Next, as shown in FIG. 5H, an interlayer insulating film IL3 is blanket deposited by the CVD method or the like. A surface of the interlayer insulating film IL3 may be planarized by the CMP, if necessary. Subsequently, as shown in FIG. 5H, an opening 70 that reaches the N-type semiconductor layer 21 is formed. The opening 70 is so formed as to penetrate through the gate electrode 60 and is used for forming the columnar structure of the NFET. Furthermore, a first gate insulating film 71 is blanket formed by the CVD method or the like. At this time, the first gate insulating film 71 is formed on a side surface and a bottom surface of the opening 70 as well. As the first gate insulating film 71, a silicon oxide film, a silicon nitride film, a hafnium oxide film, a hafnium oxynitride film or a laminated film thereof can be used for example.

Next, as shown in FIG. 5I, anisotropic etching is performed to remove the first gate insulating film 71 on other than the side surface of the opening 70. Subsequently, the columnar structure of the NFET is formed within the opening 70. More specifically, the lower source/drain section 72, the channel section 73 and the upper source/drain section 74 are formed in this order upward from the bottom of the opening 70. This is possible, for example, by selective epitaxial growth with using the silicon substrate as crystal seed to sequentially form N-type semiconductor, semiconductor and N-type semiconductor. Single-crystal semiconductor can be obtained by the epitaxial growth with using the silicon semiconductor layer as a seed. Note that the epitaxial growth may proceed over an upper end of the opening 70. In this case, an upper end of the columnar structure extends in a transverse direction as shown in FIG. 5I, which makes it easy to connect with a contact plug 92 described later.

In this manner, the NFET is formed on the N-type semiconductor layer 21. The lower source/drain section 72 among the source/drain sections 72 and 74 of the NFET is connected to the N-type semiconductor layer 21.

Next, the PFET is formed in a similar manner to the NFET. More specifically, as shown in FIG. 5J, an opening 80 that reaches the P-type semiconductor layer 22 is formed. The opening 80 is so formed as to penetrate through the gate electrode 60 and is used for forming the columnar structure of the PFET. Furthermore, a second gate insulating film 81 is blanket formed by the CVD method or the like. Subsequently, anisotropic etching is performed to remove the second gate insulating film 81 on other than a side surface of the opening 80. After that, the lower source/drain section 82, the channel section 83 and the upper source/drain section 84 are formed in this order upward from the bottom of the opening 80. In this manner, the PFET is formed on the P-type semiconductor layer 22. The lower source/drain section 82 among the source/drain sections 82 and 84 of the PFET is connected to the P-type semiconductor layer 22.

As described above, the vertical NFET is formed on the N-type semiconductor layer 21 of the same conductivity type and the vertical PFET is formed on the P-type semiconductor layer 22 of the same conductivity type. It should be noted that the formation order of the NFET and PFET can be reversed.

After that, an interlayer insulating film is blanket formed further and a surface thereof is planarized by the CMP. Then, the contact plugs 91 to 94 are formed to penetrate through the interlayer insulating film to reach the gate electrode 60, the source/drain section 74 of the NFET, the source/drain section 84 of the PFET and the second metal layer 52, respectively. Moreover, the input line In, the ground line Gnd, the power-supply line Vdd and the output line Out are formed on the contact plugs 91 to 94, respectively. Consequently, the semiconductor device 1 as shown in FIG. 2 is obtained.

According to the present embodiment, the structure shown in FIG. 2 can be formed in a self-aligned manner with a small number of processes. That is to say, it is possible to easily achieve the high-integration complementary-type semiconductor device.

Moreover, according to the present embodiment, the NFET and PFET are formed after the formation of the metal layers 51 and 52. In other words, the metal layers 51 and 52 can be formed without being influenced by the columnar structures of the NFET and PFET. Therefore, an arrangement density of the NFET and PFET can be set as high as possible, which improves the integration.

Furthermore, according to the present embodiment, the NFET and PFET are formed by forming the gate electrode 60 and then forming the openings 70 and 80 to penetrate through the gate electrode 60. Therefore, the NFET and PFET can be easily formed on the same substrate.

The present invention includes the following method of manufacturing a semiconductor device.

A method of manufacturing a semiconductor device, comprising: forming a first semiconductor layer of a first conductivity type and a second semiconductor layer of a second conductivity type on an insulating substrate, wherein said first semiconductor layer and said second semiconductor layer are directly in contact with each other; and forming a first vertical field effect transistor of said first conductivity type and a second vertical field effect transistor of said second conductivity type, wherein one of source and drain of said first vertical field effect transistor is connected to said first semiconductor layer, and one of source and drain of said second vertical field effect transistor is connected to said second semiconductor layer.

The method may further comprise: forming a metal layer to be in contact with both of said first semiconductor layer and said second semiconductor layer, after said forming said first semiconductor layer and said second semiconductor layer and before said forming said first vertical field effect transistor and said second vertical field effect transistor.

The forming said metal layer may include: forming a cover film having an opening over a contact boundary between said first semiconductor layer and said second semiconductor layer; blanket forming a metal material film; and forming said metal layer by alloying said metal material film and said first and second semiconductor layers at said opening.

### 4. MODIFICATION EXAMPLE

### 4-1. First Modification Example

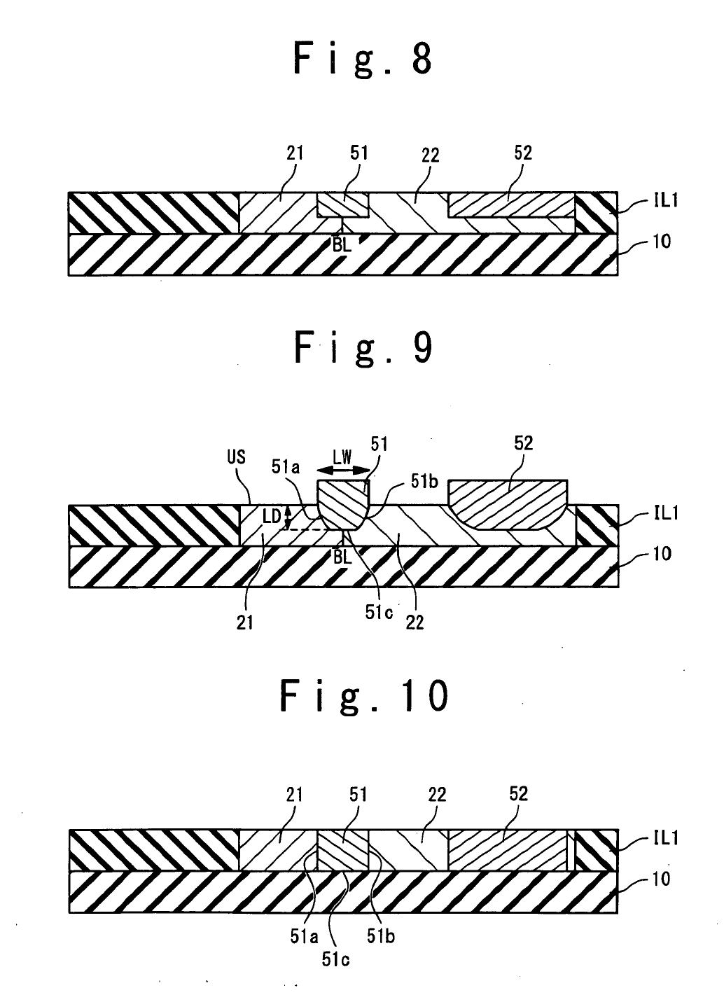

The pattern of the openings R1 and R2 of the alloying inhibition film 30 in FIG. 5D is not limited to that shown in FIG. 6. The pattern of the openings R1 and R2 of the alloying inhibition film 30 can be that shown in FIG. 7. In the example shown in FIG. 7, a part of the pattern of the openings R1 and R2 protrudes from a region where the semiconductor layers 21 and 22 are formed. In this case, at least a part of the sides of the formed metal layers 51 and 52 is defined in a self-aligned manner by the boundary of the semiconductor layers 21 and 22 as a base layer. Therefore, even if displacement of the openings R1 and R2 occurs, variability of shapes of the formed metal layers 51 and 52 can be suppressed. In the case where the openings R1 and R2 shown in FIG. 7 are used, a cross-sectional shape shown in FIG. 8 is obtained instead of that shown in the foregoing FIG. 5F. It should be noted that the right-side boundary of the second metal layer 52 is defined in a self-aligned manner by the right-side boundary of the P-type semiconductor layer 22 as shown in FIG. 8.

### 4-2. Second Modification Example

In the actual manufacturing process, the cross-sectional shape of the metal layers 51 and 52 can be rounded shape as shown in FIG. 9 instead of strict rectangle. Even in this case, the fact remains that the first metal layer 51 is formed to be embedded in the N-type semiconductor layer 21 and the P-type semiconductor layer 22. That is, the first metal layer 51 has the first side surface 51a being in contact with the N-type semiconductor layer 21, the second side surface 51b being in contact with the P-type semiconductor layer 22, and the bottom surface 51c being in contact with both of the N-type semiconductor layer 21 and the P-type semiconductor layer 22. In order to significantly reduce the contact resistance, a buried depth LD of the first metal layer 51 is more than 5% (preferably 10%) of a width LW of the first metal layer 51. The same applies to the second metal layer 52.

Moreover, it is not necessary that upper surfaces of the metal layers 51 and 52 and the upper surface US of the semiconductor layers 21 and 22 are aligned. The metal layers 51 and 52 may partially project from the semiconductor layers 21 and 22 as shown in FIG. 9. On the other hand, the whole of the metal layers 51 and 52 may sink down into the semiconductor layers 21 and 22. At least a part of the metal layers 51 and 52 each just needs to be formed below the upper surface US of the semiconductor layers 21 and 22. As a result, the contact area between the metal layers (51, 52) and the semiconductor layers (21, 22) is increased and the parasitic resistance is reduced.

### 4-3. Third Modification Example

As shown in FIG. 10, the metal layers 51 and 52 may be formed to be in contact with the insulating substrate 10. In this case, the first metal layer 51 lies between the N-type semiconductor layer 21 and the P-type semiconductor layer 22. That is to say, the N-type semiconductor layer 21 and the P-type semiconductor layer 22 are electrically connected with each other through the first metal layer 51. Also in this case, there is no need to form a device isolation structure between the N-type semiconductor layer 21 and the P-type semiconductor layer 22. The N-type semiconductor layer 21 and the P-type semiconductor layer 22 are short-circuited to each other without through a device isolation structure. Therefore, the integration is improved.

In the case of the example shown in FIG. 10, the bottom surface 51c of the first metal layer 51 is in contact with the insulating substrate 10. That is, the bottom surface 51c of the first metal layer 51 is not in contact with the N-type semiconductor layer 21 and the P-type semiconductor layer 22. The first metal layer 51 is in contact with the N-type semiconductor layer 21 at the first side surface 51a and with the P-type semiconductor layer 22 at the second side surface 51b. In order to secure the contact area sufficiently, the N-type semiconductor layer 21 and the P-type semiconductor layer 22 are preferably formed thick to some extent.

The present invention includes the following semiconductor device. A semiconductor device comprising: an insulating substrate; a first semiconductor layer of a first conductivity type formed on said insulating substrate; a first vertical field effect transistor of said first conductivity type, one of whose source and drain being formed on said first semiconductor layer; a second semiconductor layer of a second conductivity type formed on said insulating substrate; a second vertical field effect transistor of said second conductivity type, one of whose source and drain being formed on said second semiconductor layer; and a metal layer formed to be in contact with both of said first semiconductor layer and said second semiconductor layer, wherein at least a part of said metal layer is formed below an upper surface of said first semiconductor layer and said second semiconductor layer.

It is apparent that the present invention is not limited to the above embodiments and may be modified and changed without departing from the scope and spirit of the invention.

What is claimed is:

1. A semiconductor device comprising:
an insulating substrate;
a first semiconductor layer of a first conductivity type formed on said insulating substrate;
a first vertical field effect transistor of said first conductivity type, one of whose source and drain being formed on said first semiconductor layer;
a second semiconductor layer of a second conductivity type formed on said insulating substrate; and
a second vertical field effect transistor of said second conductivity type, one of whose source and drain being formed on said second semiconductor layer,
wherein said first semiconductor layer and said second semiconductor layer are directly in contact with each other.

2. The semiconductor device according to claim 1, further comprising a first metal layer formed to be in contact with both of said first semiconductor layer and said second semiconductor layer.

3. The semiconductor device according to claim 2,
wherein said first metal layer is formed over a contact boundary between said first semiconductor layer and said second semiconductor layer.

4. The semiconductor device according to claim 2,
wherein at least a part of said first metal layer is formed below an upper surface of said first semiconductor layer and said second semiconductor layer.

5. The semiconductor device according to claim 2,
wherein said first metal layer has:
a first side surface being in contact with said first semiconductor layer;
a second side surface being in contact with said second semiconductor layer; and
a bottom surface being in contact with said first semiconductor layer and said second semiconductor layer.

6. The semiconductor device according to claim 2, further comprising a second metal layer formed to be in contact with any one of said first semiconductor layer and said second semiconductor layer.

7. The semiconductor device according to claim 6,
wherein said first metal layer and said second metal layer are formed in a same layer.
